(19) United States
(12) Patent Application Publication
(10) Pub. No.: US 2026/0227431 A1
(43) Pub. Date: Aug. 6, 2026

(54) DIGITAL CONTROL APPARATUS CAPABLE OF HIGH-SPEED SAMPLING AND METHOD THEREFOR

(71) Applicant: LS ELECTRIC CO., LTD., Anyang-si, Gyeonggi-do (KR)

(72) Inventors: Sun Ho BAE, Anyang-si, Gyeonggi-do (KR); Jae Ho LEE, Anyang-si, Gyeonggi-do (KR)

(21) Appl. No.: 19/150,365

(22) PCT Filed: Jan. 29, 2024
(86) PCT No.: PCT/KR2024/001366

§ 371 Date: Jul. 23, 2025

(30) Foreign Application Priority Data
Mar. 30, 2023 (KR) 10-2023-0042209

(51) Int. Cl. G01R 19/25; H02M 1/00; H03K 7/08

(52) U.S. Cl. CPC G01R 19/2509; H02M 1/0009; H02M 1/0012; H03K 7/08

(57) ABSTRACT

The present disclosure relates to a digital control apparatus capable of high-speed sampling and a method therefor. According to the present disclosure, current or voltage sampling for controlling a PWM module of a power conversion device that is to be controlled is performed multiple times during a period of current or voltage, and thus it is possible to accurately control the digital control apparatus without considering a circuit or device delay of the digital control apparatus unlike the prior art.

### CROSS-REFERENCE TO RELATED APPLICATION

This application is the national phase entry of International Application No. PCT/KR2024/001366, filed on Jan. 29, 2024, which is based upon and claims priority to Korean Patent Application No. 10-2023-0042209, filed on Mar. 30, 2023, the entire contents of which are incorporated herein by reference.

### FIELD

The present disclosure relates to a digital control apparatus, and more particularly, to an apparatus that performs digital control through sampling.

### BACKGROUND

In power converters such as inverters and converters, not only traditional analog control but also digital control methods are widely used.

Digital control has the advantage of being easy to implement and modify, which makes it possible to readily apply various advanced control techniques.

However, digital control does not perform control using continuous signals like analog control, but rather samples continuous signals at specific time points to perform control, and thus, discontinuities caused by sampling and resulting signal distortion are inevitable.

Therefore, it is essential to compensate for such signal distortion in digital control, but in high-frequency domains, there are limitations due to sampling speed, signal processing speed, and computation speed.

FIG. 7 illustrates an example of analog-to-digital converter (ADC) sampling in a typical power converter.

In general, a power converter controls the voltage based on the inductor current (IL). Digital current control samples the inductor current and controls the current based on it, but since the sampling cannot be performed continuously like an analog signal, it is usually performed once per single period.

In FIG. 7, when the value of VCarrier reaches its peak, the inductor current is sampled, and since the inductor current has a sawtooth-shaped waveform, the average value of the inductor current needs to be measured at the sampling time point.

However, the current measurement value indicated by the dotted line is delayed due to the performance of the current sensor or filters, resulting in a difference from the actual inductor current value intended to be sampled.

To compensate for this, it is necessary to adjust for measurement delay based on the specific components and elements used, but since the required compensation varies by circuit and often relies on the engineer's experience, it becomes problematic.

The inventors of the present disclosure have conducted research to address the sampling issues in the digital control methods of the related art. After extensive efforts to develop the digital control apparatus and method capable of high-speed sampling to address the sampling delay problem in digital control apparatuses, the present disclosure has been completed.

### National R&D Project Supporting This Disclosure

[Project Code] 1415181044
[Task Number] 20210501010020
[Supervising Ministry] Ministry of Trade, Industry and Energy (MOTIE)
[Project Management (Specialized) Agency] Korea Institute of Energy Technology Evaluation and Planning (KETEP)
[Program Title] Development of Large-Capacity High-Voltage Modular ESS Technology for Renewable Energy Grid Integration (R&D)
[Project Title] Development of Core Equipment for High-Voltage Hub Station and MMC-type ESS for Renewable Energy Integration
[Contribution Rate] 1/1
[Executing Institution] Korea Electrotechnology Research Institute (KERI)
[Project Period] Nov. 1, 2021-Dec. 31, 2024

### SUMMARY

An object of the present disclosure is to provide a digital control apparatus capable of high-speed sampling and a method thereof, which can address the problem of inaccurate sampling values in digital sampling.

Meanwhile, other unspecified objectives of the present disclosure may additionally be considered within the scope that can be readily inferred from the following detailed description and its effects.

According to an aspect of the present disclosure, a digital control apparatus capable of high-speed sampling includes:
a sampler configured to sample a current or voltage of a power converter; and a controller configured to control a pulse width modulation (PWM) module to adjust an output of the power converter based on the sampled current or voltage,
wherein the sampler is configured to perform two or more samplings of the current or voltage during a single period of the current or voltage to be sampled.

The sampler may be configured to perform sampling at a maximum possible number of times during the single period of the current or voltage to be sampled.

The controller may be configured to perform control of the PWM module for each sampling of the sampler.

The controller may be configured to calculate a sampling time point corresponding to an average value of the current or voltage to be sampled after the maximum number of samplings, and the sampler may be configured to perform sampling, starting from a next period of the current or voltage to be sampled, only at the sampling time point calculated by the controller.

The sampler and the controller may be implemented in a processor that is separate from an entire system.

According to another aspect of the present disclosure, a digital control method capable of high-speed sampling includes:
sampling a current or voltage to adjust an output of a power converter; and controlling a pulse width modulation (PWM) module to adjust the output of the power converter based on the sampled current or voltage,
wherein the sampling may include performing two or more samplings of the current or voltage during a single period of the current or voltage to be sampled.

The sampling may be configured to include performing sampling at a maximum possible number of times during the single period of the current or voltage to be sampled.

The controlling of the period of the PWM module may be configured to include controlling the period of the PWM module for each sampling of the sampling.

The controlling of the period of the PWM module may be configured to include calculating a sampling time point corresponding to an average value of the current or voltage to be sampled after the maximum number of samplings, and the sampling is configured to include performing sampling only at the calculated sampling time point starting from a next period of the current or voltage to be sampled.

The sampling and the controlling of the period of the PWM module may be performed in a processor that is separate from an entire system.

According to the present disclosure, multiple samplings are performed during a period of the voltage or current to be sampled through high-speed sampling, and multiple digital controls are performed accordingly, so that compared to the case where only a single sampling is performed as in the prior art, it is possible to reduce errors caused by sampling delay.

Meanwhile, even effects not explicitly described herein shall be regarded as disclosed in the specification of the present disclosure, insofar as they are expected based on the technical features of the present disclosure and described or implied in the following specification.

### BRIEF DESCRIPTION OF THE DRAWINGS

FIG. 1 is a schematic structural diagram of a digital control apparatus capable of high-speed sampling according to a preferred embodiment of the present disclosure.

FIGS. 2 to 4 are detailed structural diagrams of a digital control apparatus capable of high-speed sampling according to a preferred embodiment of the present disclosure.

FIG. 5 illustrates an example of a sampling timing according to a preferred embodiment of the present disclosure.

FIG. 6 is a flowchart of a digital control method capable of high-speed sampling according to another preferred embodiment of the present disclosure.

FIG. 7 illustrates an example of a sampling time point according to a related art.

※ The accompanying drawings are illustrated by reference for understanding the technical idea of the present disclosure, and the scope of the present disclosure is not limited thereto.

### DETAILED DESCRIPTION

Hereinafter, the configuration of the present disclosure as guided by various embodiments and the effects resulting therefrom will be described with reference to the accompanying drawings. In the description of the present disclosure, well-known functions that are obvious to those skilled in the art may be omitted for clarity when it is determined that a detailed description would unnecessarily obscure the gist of the disclosure.

Terms such as ‘first’, ‘second’, and the like may be used to describe various elements, but the elements should not be limited by the above terms. The above terms may be used only for the purpose of distinguishing one element from another. For example, the ‘first element’ may be referred to as a ‘second element’, and similarly, the ‘second element’ may be referred to as a ‘first element’ without departing from the scope of the present disclosure. Also, the singular forms include plural forms unless the context clearly dictates otherwise. The terms used in the embodiments of the present disclosure may be interpreted as meanings commonly known to those skilled in the art unless otherwise defined.

Hereinafter, with reference to the drawings, the configuration of the present disclosure as guided by various embodiments and the effects derived therefrom will be described.

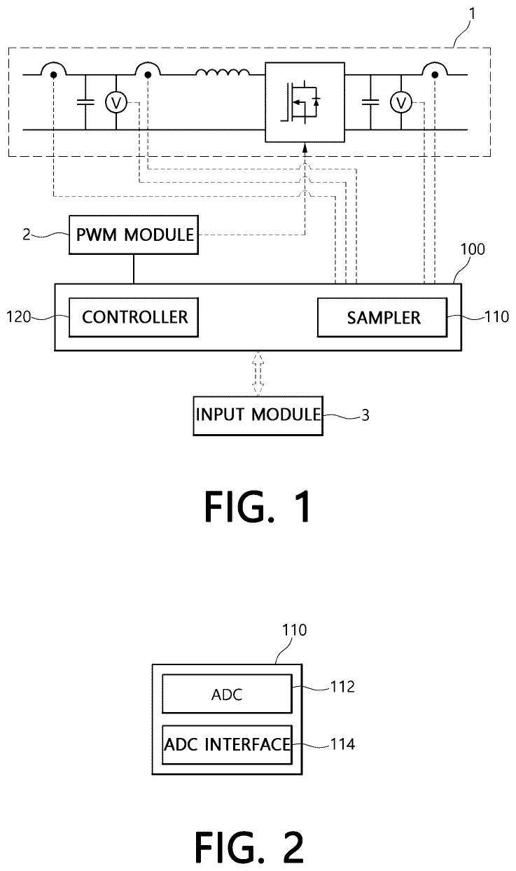

FIG. 1 is a schematic structural diagram of a digital control apparatus capable of high-speed sampling according to a preferred embodiment of the present disclosure.

The digital control apparatus 100 according to the present disclosure may include a sampler 110 and a controller 120.

The sampler 110 of the digital control apparatus 100 samples an inductor current of the power converter 1, and the controller 120 compares the sampled value with a reference input from the input module 3 and performs control of the power converter 1 by controlling the pulse width of the PWM module 2.

FIG. 2 is a more detailed structure diagram of a sampler 110 according to the present disclosure.

The sampler 110 may include an analog to digital converter (ADC) 112 and an ADC interface 114.

The ADC 112 performs high-speed sampling of the current or voltage to be sampled and converts it into a digital value, and the ADC interface 114 transmits this digital value to the controller 120.

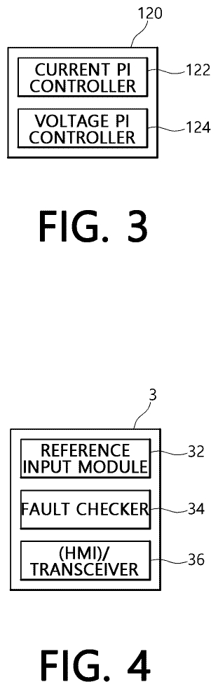

FIG. 3 is a more detailed structural diagram of the controller 120 according to the present disclosure.

The controller 120 may include a current proportional-integral (PI) controller 122 and a voltage proportional-integral (PI) controller 124.

The current PI controller 122 controls the PWM module 2 to perform proportional-integral control of the current of the power converter based on the current or voltage sampled by the sampler 110.

Similarly, the voltage PI controller 124 controls the PWM module 2 to perform proportional-integral control of the voltage of the power converter based on the current or voltage sampled by the sampler 110.

FIG. 4 illustrates a more detailed structure of the input module 3 for digital control of the power converter.

The reference input module 32 provides a reference value for the proportional-integral (PI) control performed by the controller 120.

That is, since the current PI controller 122 or the voltage PI controller 124 performs control to reduce an error between the reference input and the actual sampled value (measured value) of the power converter 1, the reference input is necessary.

The human machine interface (HMI)/transceiver 36 receive user input or communicate with other devices, and errors such as those in the ADC interface 114 are detected by the fault checker 34.

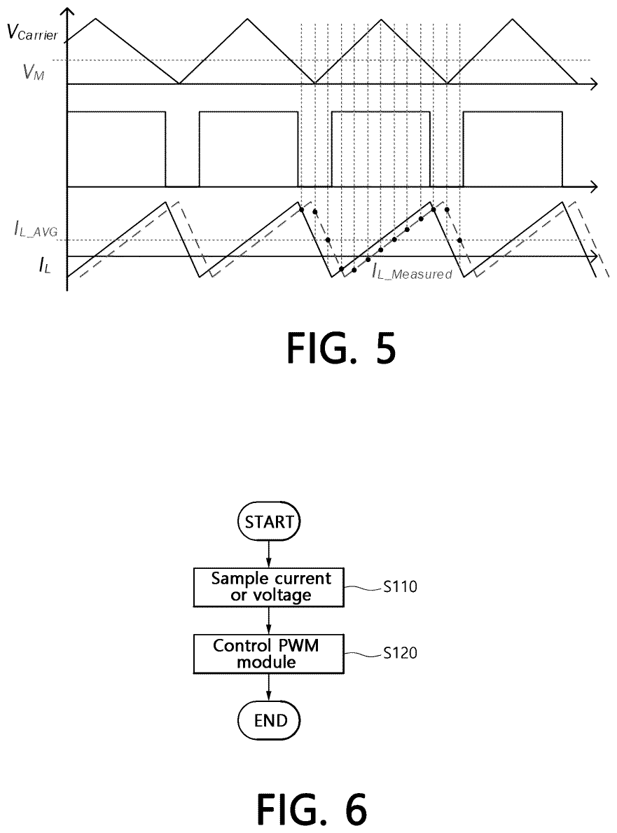

FIG. 5 illustrates an example of sampling performed by the digital control apparatus 100 according to the present disclosure.

Unlike the related art, two or more samplings of the inductor current IL within a single period of VCarrier are performed by the sampler 110, and the controller 120 performs current or voltage PI control for each sampling of the sampler 110 based on the sampling result. Accordingly, a plurality of digital controls are performed during a single period, and the sampled values become closer to an average value of the current or voltage to be sampled.

In the example of FIG. 5, the number of samplings within a single period is illustrated as 10, but is not limited to this number.

Since the digital control apparatus 100 according to the present disclosure is capable of high-speed sampling, sampling may be performed at a rate of 10 times or more within a single period of the current or voltage to be sampled. Accordingly, the controller 120 performs digital control at every sampling time rather than once per period.

In a preferred embodiment, the sampling and digital control may be performed at the maximum possible speed (number of times) of the digital control apparatus 100. When the sampling and digital control are performed at the maximum speed, they become closer to analog control, and thus, control by the average value of the sampled current or voltage may be achieved without considering delays caused by digital filters or components of the control apparatus, as in the related art.

To this end, the digital control apparatus 100 may be independently configured with a separate processor (CPU) from the entire system, and the overall system may thus be configured as a multicore system.

In another preferred embodiment of the present disclosure, the sampler 110 performs sampling for the current or voltage at the maximum possible speed.

The controller 120 may obtain an average value of the sampled current or voltage and calculate a sampling time point corresponding to the average value.

Starting from the next period after performing sampling at the maximum speed, the sampler 110 performs sampling only at the sampling time point corresponding to the average value of the current or voltage calculated by the controller 120, and using this value, the controller 120 performs current or voltage PI control, which enables digital control based on the average value while reducing processor usage, thereby alleviating the overall load on the system.

When the present disclosure is implemented in a single-core system, the controller 120 may determine the system load, and if the load is low, the digital control apparatus 100 performs sampling and control at the maximum possible speed, and if the load is high, the controller may calculate a sampling time point corresponding to the average value of the current or voltage, and sampling and control are then performed only at that time point, as described above, thereby reducing the overall system load.

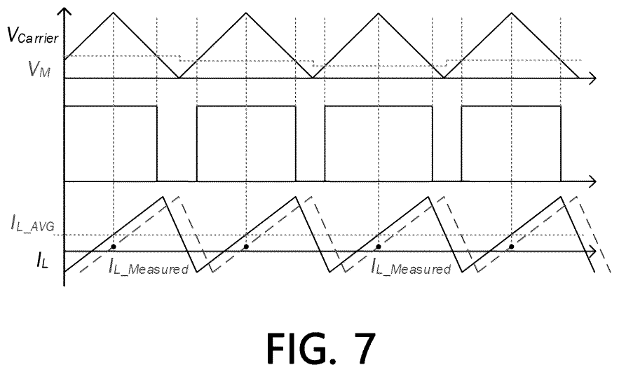

FIG. 6 is a schematic flowchart of a digital control method capable of high-speed sampling according to another preferred embodiment of the present disclosure.

The digital control method according to the present disclosure may be performed by the sampler and the controller.

To perform digital control, sampling of the current or voltage is first performed (step S110).

The sampling may be performed multiple times within a single period of the current or voltage to be sampled. Preferably, the sampling may be performed ten times or more, or up to the maximum number of times possible in the sampler and the controller.

Then, the PWM module is controlled based on the sampled current or voltage (step S120).

The control of the PWM module is performed by controlling the output PWM of the PWM module through PI control of the current or voltage, and accordingly, the output voltage or current of the power converter is controlled.

The PWM module is controlled as many times as the number of samplings in the sampling step. That is, two or more samplings are performed within a single period of the current or voltage to be sampled, and the controller performs digital control for each sampling.

Preferably, the digital control method according to the present disclosure is performed at the maximum sampling speed supported by the performance of the sampler and the controller.

When the sampling is performed at the maximum speed as described above, the control of the PWM module is also performed at the maximum speed, so that the digital control method achieves an effect similar to that of analog control.

For this purpose, the digital control method according to the present disclosure may be performed by an independent processor separate from the entire system.

If the control of the entire system, including the digital control method, is performed by one processor, an average value of the current or voltage among the results sampled at the maximum speed may be obtained in the PWM module cycle control step, and the time point at which the average value was sampled may be obtained. In the subsequent sampling step, sampling is performed only at the time point at which the average value was sampled, allowing accurate sampling of the average voltage or current without delay compensation, and starting from the next period of the voltage or current, this also reduces the load on the overall system.

According to the digital control apparatus and method capable of high-speed sampling as described above, unlike the related art, sampling and the corresponding digital control are performed multiple times, preferably at the maximum possible speed of the digital control apparatus, within a single period, thereby solving the problem of sampling delay encountered in the related art.

The scope of the present disclosure is not limited to the description and expression of the exemplary embodiments explicitly described above. In addition, it is again to note that the scope of the present disclosure may not be limited because it is obvious to changes or substitutions in the art to which the present disclosure pertains.

1. A digital control apparatus capable of high-speed sampling, comprising:
a sampler configured to sample a current or voltage of a power converter; and
a controller configured to control a pulse width modulation (PWM) module to adjust an output of the power converter based on the sampled current or voltage,
wherein the sampler is configured to perform two or more samplings of the current or voltage during a single period of the current or voltage to be sampled.

2. The digital control apparatus of claim 1, wherein the sampler is configured to perform sampling at a maximum possible number of times during the single period of the current or voltage to be sampled.

3. The digital control apparatus of claim 2, wherein the controller is configured to perform control of the PWM module for each sampling of the sampler.

4. The digital control apparatus of claim 2, wherein the controller is configured to calculate a sampling time point corresponding to an average value of the current or voltage to be sampled after the maximum number of samplings, and
the sampler is configured to perform sampling, starting from a next period of the current or voltage to be sampled, only at the sampling time point calculated by the controller.

5. The digital control apparatus of claim 1, wherein the sampler and the controller are implemented in a processor that is separate from an entire system.

6. A digital control method capable of high-speed sampling, comprising:
sampling a current or voltage to adjust an output of a power converter; and
controlling a pulse width modulation (PWM) module to adjust the output of the power converter based on the sampled current or voltage,
wherein the sampling is configured to include performing two or more samplings of the current or voltage during a single period of the current or voltage to be sampled.

7. The digital control method of claim 6, wherein the sampling is configured to include performing sampling at a maximum possible number of times during the single period of the current or voltage to be sampled.

8. The digital control method of claim 7, wherein the controlling of the period of the PWM module is configured to include controlling the period of the PWM module for each sampling of the sampling.

9. The digital control method of claim 7, wherein the controlling of the period of the PWM module is configured to include calculating a sampling time point corresponding to an average value of the current or voltage to be sampled after the maximum number of samplings, and
the sampling is configured to include performing sampling only at the calculated sampling time point starting from a next period of the current or voltage to be sampled.

10. The digital control method of claim 6, wherein the sampling and the controlling of the period of the PWM module are performed in a processor that is separate from an entire system.
